(19) United States
(12) Patent Application Publication
(10) Pub. No.: US 2023/0142939 A1
(43) Pub. Date: May 11, 2023

(54) MANUFACTURING METHOD OF SiC SUBSTRATE

(71) Applicant: DISCO CORPORATION, Tokyo (JP)

(72) Inventor: Katsuyoshi KOJIMA, Tokyo (JP)

(21) Appl. No.: 18/054,204

(22) Filed: Nov. 10, 2022

(30) Foreign Application Priority Data
Nov. 11, 2021 (JP) 2021-183907

(51) Int. Cl. B24B 7/22

(52) U.S. Cl. CPC B24B 7/228

(57) ABSTRACT

A method of manufacturing a SiC substrate includes grinding a sliced SiC substrate on a side of its front surface on which a Si-face is exposed, grinding the sliced SiC substrate on a side of its back surface on which a C-face is exposed, such that the back surface has an arithmetic mean height Sa of 1 nm or less, and then polishing the sliced SiC substrate on the side of only the front surface and not on the side of the back surface. In a case where the side of the back surface is ground as described above, the SiC substrate can be prevented from being warped even if the side of the back surface is not polished. This can shorten the manufacturing lead time for the SiC substrate used for the manufacture of power devices or the like and can also reduce the manufacturing cost.

### BACKGROUND OF THE INVENTION

### Field of the Invention

The present invention relates to a manufacturing method of a silicon carbide (SiC) substrate.

### Description of the Related Art

A power device such as an inverter or a converter is required to have large current capacity and high withstand voltage. To meet such requirements, power devices are often manufactured using a SiC substrate. Such a SiC substrate is typically manufactured from a SiC ingot.

For example, a SiC substrate is sliced from a SiC ingot with use of a wire saw or the like such that a silicon (Si)-face is exposed on a front surface and a carbon (C)-face is exposed on a back surface. It is to be noted that the Si-face is a surface terminated in Si and is expressed to be a (0001) plane by the Miller index notation. It is also to be noted that the C-face is a surface terminated in C and is expressed to be a (000-1) plane by the Miller index notation.

On the SiC substrate, the epitaxial growth of a SiC thin film on the Si-face is easier than that of a SiC thin film on the C-face. When manufacturing power devices with use of such a SiC substrate, the power devices are therefore typically formed on a side of a front surface on which a Si-face is exposed.

When an as-sliced SiC substrate (hereinafter simply called a “sliced SiC substrate”) is sliced from a SiC ingot, the sliced SiC substrate is however prone to be rough at its front surface and back surface (prone to have large irregularities formed at its front surface and back surface). If the front surface of the sliced SiC substrate is rough, it is difficult to allow an epitaxial growth of a SiC thin film on the front surface. There is hence a need to planarize (mirror-finish) the front surface of the sliced SiC substrate before power devices are manufactured using the sliced SiC substrate.

If the sliced SiC substrate is planarized only on its front surface, however, the resulting SiC substrate may significantly be warped due to a difference in roughness between its front surface and its back surface. A SiC substrate for use in the manufacture of power devices is hence manufactured by polishing and planarizing on the sides of both its front surface and back surface after grinding on both the sides of the front and back surfaces to reduce their roughness (see, for example, Japanese Patent Laid-open No. 2017-105697).

### SUMMARY OF THE INVENTION

If power devices are formed on the side of only a front surface of a SiC substrate on which a Si-face is exposed, the planarization of the back surface of a sliced SiC substrate on which a C-face is exposed does not directly affect the performance of the power devices. On the contrary, the application of polishing not only to the side of a front surface but also to the side of the back surface of the sliced SiC substrate results in longer manufacturing lead time and also higher manufacturing cost.

With the foregoing in view, the present invention has as an object thereof the provision of a manufacturing method of a SiC substrate that can shorten the manufacturing lead time for the SiC substrate and can also reduce the manufacturing cost of the same.

In accordance with an aspect of the present invention, there is provided a manufacturing method of a SiC substrate. The manufacturing method includes a separation step of separating a sliced SiC substrate from a SiC ingot such that a Si-face is exposed on a front surface and a C-face is exposed on a back surface, a grinding step of, after the separation step, grinding the sliced SiC substrate on both a side of the front surface and a side of the back surface of the sliced SiC substrate, and a polishing step of, after the grinding step, polishing the sliced SiC substrate only on the side of the front surface and not on the side of the back surface. The grinding step includes a first grinding step of grinding the sliced SiC substrate on the side of the front surface and a second grinding step of grinding the sliced SiC substrate on the side of the back surface. In the second grinding step, the sliced SiC substrate is ground on the side of the back surface such that the back surface has an arithmetic mean height Sa of 1 nm or less.

Preferably, the second grinding step may be performed using grinding stones that contain abrasive grits having an average grit size of 0.3 μm or smaller.

In the present invention, the sliced SiC substrate is ground on the side of the front surface on which the Si-face is exposed, and is also ground on the side of the back surface on which the C-face is exposed, such that the back surface has the arithmetic mean height Sa of 1 nm or less, and the sliced SiC substrate is then polished only on the side of the front surface and not on the side of the back surface. If the sliced SiC substrate is ground on the side of the back surface as described above, the warpage of the resulting SiC substrate can be suppressed without the sliced SiC substrate being further polished on the side of the back surface. According to the present invention, it is hence possible to shorten the manufacturing lead time for a SiC substrate for use in the manufacture of power devices or the like, and to also reduce its manufacturing cost.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flow chart schematically illustrating a manufacturing method according to an embodiment of the present invention for a SiC substrate;

FIG. 2 is a perspective view schematically illustrating an example of a sliced SiC substrate separated from a SiC ingot;

FIG. 3 is a perspective view schematically illustrating an example of a processing apparatus useful in the practice of the manufacturing method of FIG. 1;

FIG. 4A is a side view schematically illustrating how the sliced SiC substrate is ground on a side of a front surface thereof;

FIG. 4B is a side view schematically illustrating how the sliced SiC substrate is ground on a side of a back surface thereof; and

FIG. 5 is a partly cross-sectional side view schematically illustrating how the sliced SiC substrate is polished on the side of the front surface thereof.

### DETAILED DESCRIPTION OF THE PREFERRED EMBODIMENT

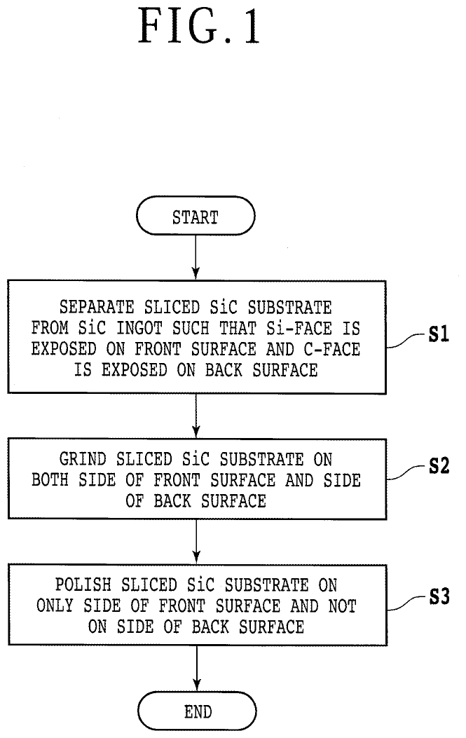

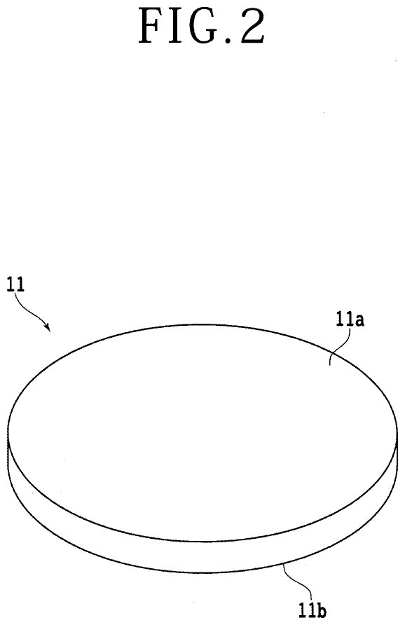

With reference to the attached drawings, a description will be made with regard to an embodiment of the present invention. FIG. 1 is a flow chart schematically illustrating a manufacturing method according to the embodiment of the present invention for a SiC substrate. In this method, a sliced SiC substrate is separated from a cylindrical SiC ingot such that a Si-face is exposed on a front surface thereof and a C-face is exposed on a back surface thereof (separation step: S1). FIG. 2 is a perspective view schematically illustrating an example of the sliced substrate separated from the SiC ingot.

The sliced SiC substrate 11 illustrated in FIG. 2 has been sliced from the SiC ingot such that the Si-face is exposed on its front surface 11a and the C-face is exposed on its back surface 11b. This separation step (S1) is performed by slicing of the sliced SiC substrate 11 from the SiC ingot, for example, with a wire saw such as a diamond wire saw.

As an alternative, the separation step (S1) may also be performed by separation of the sliced SiC substrate 11 from the SiC ingot with a laser beam of a wavelength (for example, 1064 nm) that transmits SiC. If this is the case, the laser beam is first applied to the SiC ingot with a focal point of the laser beam positioned at a predetermined depth from a surface of the SiC ingot (a depth corresponding to a thickness of the sliced SiC substrate 11 to be separated).

As a consequence, a separation layer is formed inside the SiC ingot. An external force is then applied to the SiC ingot. As a result, the SiC ingot is split with the separation layer being used as a starting point of separation. In other words, the sliced SiC substrate 11 is separated from the SiC ingot.

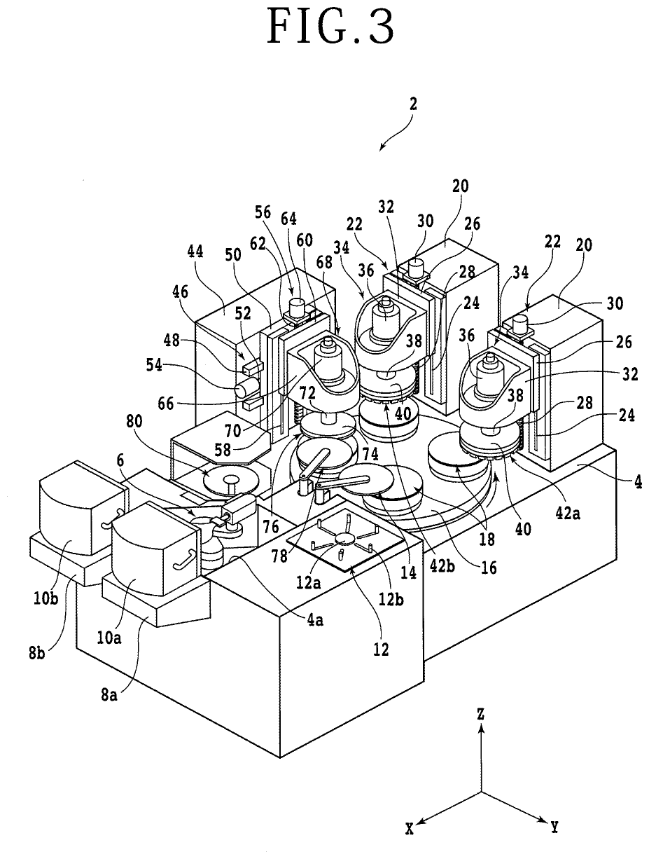

After the sliced SiC substrate 11 has been ground on both the side of the front surface 11a and the side of the back surface 11b (grinding step: S2), the sliced SiC substrate 11 is next polished only on the side of the front surface 11a and not on the side of the back surface 11b (polishing step: S3). FIG. 3 is a perspective view schematically illustrating an example of a processing apparatus that is useful in the practice of the manufacturing method of FIG. 1, specifically, that can grind and polish the sliced SiC substrate.

It is to be noted that an X-axis direction (front-to-rear direction) and a Y-axis direction (left-to-right direction) illustrated in FIG. 3 are perpendicular to each other on a horizontal plane and that a Z-axis direction (up-to-down direction) is perpendicular (vertical) to the X-axis direction and Y-axis direction.

A processing apparatus 2 illustrated in FIG. 3 includes a bed 4 that supports individual elements. A recessed section 4a is formed in an upper surface of the bed 4 at a location on a front side thereof, and in the recessed section 4a, a transfer mechanism 6 is disposed to transfer the sliced SiC substrate 11 in a suction-held state. The transfer mechanism 6 can also reverse the sliced SiC substrate 11 upside down while holding the same.

In front of the recessed section 4a, cassette tables 8a and 8b are disposed. Mounted on these cassette tables 8a and 8b are cassettes 10a and 10b which can each accommodate a plurality of sliced SiC substrates 11 or manufactured SiC substrates. Diagonally behind the recessed section 4a, a position adjustment mechanism 12 is disposed to adjust the position of the sliced SiC substrate 11.

This position adjustment mechanism 12 includes, for example, a table 12a configured to enable supporting of the sliced SiC substrate 11 at a central portion thereof and a plurality of pins 12b configured to be movable toward and away relative to the table 12a in a region outside the table 12a. Loaded onto this table 12a is, for example, the sliced SiC substrate 11 unloaded from the cassette 10a by the transfer mechanism 6.

At the position adjustment mechanism 12, alignment is then performed for the sliced SiC substrate 11 loaded on the table 12a. Described specifically, the pins 12b are brought toward the table 12a until they come into contact with a side surface of the sliced SiC substrate 11 loaded on the table 12a, whereby the position of a center of the sliced SiC substrate 11 is aligned with a predetermined position on a plane (XY plane) parallel to the X-axis direction and Y-axis direction.

In the vicinity of the position adjustment mechanism 12, a transfer mechanism 14 is disposed to swing such that the sliced SiC substrate 11 is transferred in a suction-held state. This transfer mechanism 14 includes a suction pad that can suction the sliced SiC substrate 11 on the side of an upper side thereof, and transfers the sliced SiC substrate 11 the position of which has been adjusted by the position adjustment mechanism 12, rearward. Behind the transfer mechanism 14, a disk-shaped turn table 16 is disposed.

This turn table 16 is connected to a rotary drive source (not illustrated) such as a motor, and rotates, using as an axis of rotation, a straight line that extends through a center of the turn table 16 and that is parallel to the Z-axis direction. On an upper surface of the turn table 16, a plurality of (for example, four) chuck tables 18 are disposed at substantially equal intervals along a peripheral direction of the turn table 16.

The transfer mechanism 14 then unloads the sliced SiC substrate 11 from the table 12a of the position adjustment mechanism 12, and loads it onto the chuck table 18 placed at a loading and unloading position in the vicinity of the transfer mechanism 14. The turn table 16 rotates, for example, in a direction indicated by an arrow in FIG. 3, and moves each chuck table 18 to the loading and unloading position, a coarse grinding position, a finish grinding position, and a polishing position in this order.

Each chuck table 18 is connected to a suction source (not illustrated) such as a vacuum pump, and can hold the sliced SiC substrate 11 that is placed on an upper surface of the chuck table 18, by causing a suction force to act on the sliced SiC substrate 11. Each chuck table 18 is also connected to a rotary drive source (not illustrated) such as a motor, and by power of the rotary drive source, can rotate using, as an axis of rotation, a straight line that extends through a center of the chuck table 18 and that is parallel to the Z-axis direction.

Behind the coarse grinding position and the finish grinding position (behind the turn table 16), columnar support structures 20 are disposed, respectively. On a front surface of each support structure 20 (a surface on a side of the turn table 16), a Z-axis moving mechanism 22 is disposed. This Z-axis moving mechanism 22 has a pair of guide rails 24 fixed on the front surface of the corresponding support structure 20 and extending along the Z-axis direction.

On a side of front surfaces of the paired guide rails 24, a corresponding moving plate 26 is connected in a fashion that it is slidable along the paired guide rails 24. Between the paired guide rails 24, a corresponding screw shaft 28 extending along the Z-axis direction is disposed. To an upper end portion of the screw shaft 28, a corresponding motor 30 is connected to rotate the screw shaft 28.

On a surface of the screw shaft 28 in which a helical groove is formed, a nut portion (not illustrated) is disposed with numerous balls, which roll on the surface of the rotating screw shaft 28, accommodated therein, so that a ball screw is configured. Rotation of the screw shaft 28 hence causes the numerous balls to circulate in the nut portion, whereby the nut portion moves along the Z-axis direction.

This nut portion is fixed on a side of a rear surface (back surface) of the moving plate 26. When the screw shaft 28 is rotated by the motor 30, the moving plate 26 thus moves together with the nut portion along the Z-axis direction. On a surface (front surface) of the moving plate 26, a corresponding holder 32 is disposed.

This holder 32 supports a corresponding grinding unit 34 to grind the sliced SiC substrate 11. The grinding unit 34 includes a corresponding spindle housing 36 fixed on the holder 32. In this spindle housing 36, a corresponding spindle 38 is accommodated in a rotatable fashion. The spindle 38 extends along the Z-axis direction.

To an upper end portion of each spindle 38, a rotary drive source (not illustrated) such as a motor is connected. By power of this rotary drive source, the spindle 38 can rotate using, as an axis of rotation, a straight line that is parallel to the Z-axis direction. On the other hand, the spindle 38 is exposed at a lower end portion thereof from a lower surface of the spindle housing 36, and a corresponding disk-shaped mount 40 is fixed on the lower end portion.

On a lower surface of the mount 40 of the grinding unit 34 on a side of the coarse grinding position, a coarse grinding wheel 42a is secured. This coarse grinding wheel 42a has a disk-shaped wheel base having substantially the same diameter as the mount 40. On a lower surface of this wheel base, a plurality of grinding stones (coarse grinding stones) each having a parallelepiped shape are fixed.

Similarly, on a lower surface of the mount 40 of the grinding unit 34 on a side of the finish grinding position, a finish grinding wheel 42b is secured. This finish grinding wheel 42b includes a disk-shaped wheel base having substantially the same diameter as the mount 40. On a lower surface of this wheel base, a plurality of grinding stones (finish grinding stones) each having a parallelepiped shape are fixed.

The coarse grinding stones and the finish grinding stones each contain abrasive grits made, for example, of diamond, cubic boron nitride (cBN), or the like and a binder that holds these abrasive grits. As the binder, a metal bond, a resin bond, a vitrified bond, or the like is used, for example.

It is to be noted that the abrasive grits contained in the finish grinding stones typically have a smaller average grit size than those contained in the coarse grinding stones. For example, the average grit size of the abrasive grits contained in the coarse grinding stones is 0.5 μm or greater but 30 μm or smaller, and the average grit size of the abrasive grits contained in the finish grinding stones is smaller than 0.5 μm.

In the vicinity of each of the grinding wheels 42a and 42b, liquid supply nozzles (not illustrated) are arranged to supply liquid (grinding liquid) such as pure water to processing points to be used when the sliced SiC substrate 11 is to be ground. Alternatively, in place of or in addition to the nozzles, openings may be disposed in the grinding wheels 42a and 42b to supply the grinding liquid, and the grinding liquid may be supplied to processing points via the openings.

Beside the polishing position (beside the turn table 16), a support structure 44 is disposed. On a side surface of the support structure 44, the side surface being on a side of the turn table 16, an X-axis moving mechanism. 46 is disposed. This X-axis moving mechanism 46 has a pair of guide rails 48 fixed on the side surface of the support structure 44, the side surface being on the side of the turn table 16, and extending along the X-axis direction.

On surfaces of the paired guide rails 48, the surfaces being on the side of the turn table 16, a moving plate 50 is connected in a fashion that it is slidable along the paired guide rails 48. Between the paired guide rails 48, a screw shaft 52 extending along the X-axis direction is disposed. To a front end portion of the screw shaft 52, a motor 54 is connected to rotate the screw shaft 52.

On a surface of the screw shaft 52 in which a helical groove is formed, a nut portion (not illustrated) is disposed with numerous balls, which roll on the surface of the rotating screw shaft 52, accommodated therein, so that a ball screw is configured. Rotation of the screw shaft 52 hence causes the numerous balls to circulate in the nut portion, whereby the nut portion moves along the X-axis direction.

This nut portion is fixed on a side of a surface (back surface) of the moving plate 50, the surface (back surface) being opposite the support structure 44. When the screw shaft 52 is rotated by the motor 54, the moving plate 50 thus moves together with the nut portion along the X-axis direction. On a surface (front surface) of the moving plate 50, the surface (front surface) being on the side of the turn table 16, a Z-axis moving mechanism 56 is disposed.

This Z-axis moving mechanism 56 has a pair of guide rails 58 fixed on the front surface of the moving plate 50 and extending along the Z-axis direction. On surfaces of the paired guide rails 58, the surfaces being on the side of the turn table 16, a moving plate 60 is connected in a fashion that it is slidable along the paired guide rails 58.

Between the paired guide rails 58, a screw shaft 62 extending along the Z-axis direction is disposed. To an upper end portion of the screw shaft 62, a motor 64 is connected to rotate the screw shaft 62. On a surface of the screw shaft 62 in which a helical groove is formed, a nut portion (not illustrated) is disposed with numerous balls, which roll on the surface of the rotating screw shaft 62, accommodated therein, so that a ball screw is configured.

Rotation of the screw shaft 62 hence causes the numerous balls to circulate in the nut portion, whereby the nut portion moves along the Z-axis direction. This nut portion is fixed on a side of a surface (rear surface) of the moving plate 60, the surface (rear surface) being opposite the moving plate 50. When the screw shaft 62 is rotated by the motor 64, the moving plate 60 thus moves together with the nut portion along the Z-axis direction.

On a surface (front surface) of the moving plate 60, the surface (front surface) being on the side of the turn table 16, a holder 66 is disposed. This holder 66 supports a polishing unit 68 to polish the sliced SiC substrate 11. The polishing unit 68 includes a spindle housing 70 fixed on the holder 66.

In this spindle housing 70, a spindle 72 is accommodated in a rotatable fashion. The spindle 72 extends along the Z-axis direction. To an upper end portion of the spindle 72, a rotary drive source (not illustrated) such as a motor is connected. By power of this rotary drive source, the spindle 72 is rotated.

On the other nd, the spindle 72 is exposed at a lower end portion thereof from a lower surface of the spindle housing 70, and a disk-shaped mount 74 is fixed on the lower end portion. On a lower surface of the mount 74, a disk-shaped polishing pad 76 is secured. This polishing pad 76 has a disk-shaped base having substantially the same diameter as the mount 74.

On a lower surface of this base, a disk-shaped polishing layer of substantially the same diameter as the mount 74 is fixed. This polishing layer is a fixed abrasive grit layer with abrasive grits dispersed thereinside. The polishing layer is produced, for example, by impregnation of a nonwoven fabric, which is made from a polyester, with a urethane solution in which abrasive grits of 0.4 to 0.6 μm average grit size are dispersed, and then drying of the impregnated nonwoven fabric.

The abrasive grits to be dispersed inside the polishing layer are formed of such a material as SiC, cBN, diamond, or fine metal oxide particles. As the fine metal oxide particles, fine particles made of silica (SiO₂), ceria (CeO₂), zirconia (ZrO₂), alumina (Al₂O₃), or the like are used. The polishing layer is pliable, and slightly flexes according to pressures applied when the sliced SiC substrate 11 is being polished.

Radial center positions of the spindle 72, the mount 74, and the base and polishing layer of the polishing pad 76 substantially coincide together, and a cylindrical through-hole is formed to extend through these center positions. This through-hole is in communication with a polishing liquid supply source (not illustrated) that supplies liquid (polishing liquid) such as pure water to processing points to be used when the sliced SiC substrate 11 is to be polished.

This polishing liquid supply source has a reservoir, a supply pump, and the like for the polishing liquid. The polishing liquid supply source supplies the polishing liquid toward the chuck table 18 that is positioned at the polishing position, via the through-hole formed in the spindle 72 and the like. It is to be noted that abrasive grits may be contained or may not be contained in the polishing liquid.

Beside the transfer mechanism 14, a transfer mechanism 78 is disposed to swing such that the sliced SiC substrate 11 is transferred in a suction-held state. This transfer mechanism 78 includes a suction pad that can suction the sliced SiC substrate 11 on the side of an upper side thereof, and transfers the sliced SiC substrate 11 that is placed on the chuck table 18 positioned at the loading and unloading position, forward.

In front of the transfer mechanism 78 and on a rear side of the recessed section 4a, a rinsing system 80 is disposed. This rinsing system 80 is configured such that the sliced SiC substrate 11 that has been unloaded by the transfer mechanism 78 can be rinsed on the side of the upper side thereof. The sliced SiC substrate 11 rinsed by the rinsing system 80 is then transferred and placed, for example, in the cassette 10b by the transfer mechanism 6.

On the processing apparatus 2, the grinding step (S2) and the polishing step (S3) are performed, for example, in the following order. With the sliced SiC substrate 11 accommodated in the cassette 10a being suctioned on the side of the front surface 11a, the transfer mechanism 6 first unloads the sliced SiC substrate 11 from the cassette 10a, and loads the sliced SiC substrate 11 onto the table 12a of the position adjustment mechanism 12 such that the front surface 11a is directed upward. The pins 12b are then brought into contact with the sliced SiC substrate 11 such that alignment of the sliced SiC substrate 11 is performed.

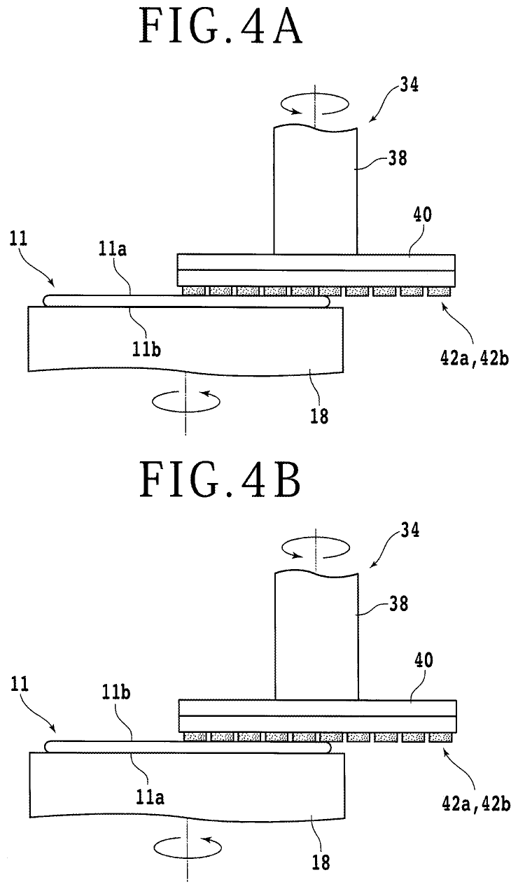

With the thus-aligned sliced SiC substrate 11 being suctioned on the side of: the front surface 11a, the transfer mechanism 14 next unloads the sliced SiC substrate 11 from the table 12a, and loads it onto the chuck table 18 placed at the loading and unloading position such that the front surface 11a is directed upward. The chuck table 18 with the sliced SiC substrate 11 loaded thereon then holds under suction the sliced SiC substrate 11 on the side of the back surface (lower surface) 11b. As illustrated in FIG. 4A, the sliced SiC substrate 11 is next polished on the side of the front surface 11a.

Described specifically, the turn table 16 is first rotated such that the chuck table 18 with the sliced SiC substrate 11 held thereon is positioned at the coarse grinding position. While rotating both the chuck table 18 and the spindle 38 of the grinding unit 34 on the side of the coarse grinding position, the Z-axis moving mechanism 22 then lowers the grinding unit 34 on the side of the coarse grinding position such that the coarse grinding stones of the grinding wheel 42a and the front surface (upper surface) 11a of the sliced SiC substrate 11 are brought into contact with each other.

As a consequence, the sliced SiC substrate 11 is subjected to coarse grinding on the side of the front surface 11a. During this time, the grinding liquid is supplied to contact interfaces (processing points) between the coarse grinding stones of the grinding wheel 42a and the front surface 11a of the sliced SiC substrate 11. The rotational speeds of the chuck table 18 and the spindle 38 during this time are each, for example, 1000 rpm or higher but 5000 rpm or lower. Further, the lowering speed of the grinding unit 34 in the state in which the coarse grinding stones of the grinding wheel 42a and the front surface 11a of the sliced SiC substrate 11 are in contact with each other is, for example, 1 μm/sec or higher but 10 μm/sec or lower.

The Z-axis moving mechanism 22 next raises the grinding unit 34 on the side of the coarse grinding position such that the coarse grinding stones of the grinding wheel 42a and the front surface (upper surface) 11a of the sliced SiC substrate 11 separate from each other. The rotation of both the chuck table 18 and the spindle 38 of the grinding unit 34 on the side of the coarse grinding position is then stopped. The turn table 16 is then rotated such that the chuck table 18 with the sliced SiC substrate 11 held thereon is positioned at the finish grinding position.

While rotating both the chuck table 18 and the spindle 38 of the grinding unit 34 on the side of the finish grinding position, the Z-axis moving mechanism 22 then lowers the grinding unit 34 on the side of the finish grinding position such that the finish grinding stones of the grinding wheel 42b and the front surface (upper surface) 11a of the sliced SiC substrate 11 are brought into contact with each other.

As a consequence, the sliced SiC substrate 11 is subjected to finish grinding on the side of the front surface 11a. During this time, the grinding liquid is supplied to contact interfaces (processing points) between the finish grinding stories of the grinding wheel 42b and the front surface 11a of the sliced SiC substrate 11. The rotational speeds of the chuck table 18 and the spindle 38 during this time are each, for example, 1000 rpm or higher but 5000 rpm or lower. Further, the lowering speed of the grinding unit 34 in the state in which the finish grinding stones of the grinding wheel 42b and the front surface 11a of the sliced SiC substrate 11 are in contact with each other is, for example, lower than 1 μm/sec.

The Z-axis moving mechanism 22 next raises the grinding unit 34 on the side of the finish grinding position such that the finish grinding stones of the grinding wheel 42b and the front surface (upper surface) 11a of the sliced SiC substrate 11 separate from each other. The rotation of both the chuck table 18 and the spindle 38 of the grinding unit 34 on the side of the finish grinding position is then stopped. The grinding of the sliced SiC substrate 11 on the side of the front surface 11a (first grinding step) has now been completed.

The turn table 16 is next rotated such that the chuck table 18 with the sliced SiC substrate 11 held thereon passes the polishing position and is positioned at the loading and unloading position. The chuck table 18 positioned at the loading and unloading position is then caused to stop the suction of the sliced SiC substrate 11 on the side of the back surface (lower surface) 11b.

In a state in which the sliced SiC substrate 11 placed on the chuck table 18 is suctioned on the side of the front surface (upper surface) 11a, the transfer mechanism 78 next unloads the sliced SiC substrate 11 from the chuck table 18, and loads it into the rinsing system 80 such that the front surface 11a is directed upward. The rinsing system 80 then rinses the sliced SiC substrate 11 on the side of the front surface 11a.

With the sliced SiC substrate 11 suctioned on the side of the back surface 11b, the transfer mechanism 6 next unloads the sliced SiC substrate 11 from the rinsing system 80, and loads the sliced SiC substrate 11 onto the table 12a of the position adjustment mechanism 12 such that the back surface 11b is directed upward. The pins 12b are then brought into contact with the sliced SiC substrate 11 such that alignment of the sliced SiC substrate 11 is performed.

With the thus-aligned sliced SiC substrate 11 suctioned on the side of the back surface 11b, the transfer mechanism 14 next unloads the sliced SiC substrate 11 from the table 12a, and loads it onto the chuck table 18 placed at the loading and unloading position such that the back surface 11b is directed upward. The chuck table 18 with the sliced SiC substrate 11 loaded thereon then holds under suction the sliced SiC substrate 11 on the side of the front surface (lower surface) 11a. As illustrated in FIG. 4B, the sliced SiC substrate 11 is next ground on the side of the back surface 11b.

Described specifically, the turn table 16 is first rotated such that the chuck table 18 with the sliced SiC substrate 11 held thereon is positioned at the coarse grinding position. While rotating both the chuck table 18 and the spindle 38 of the grinding unit 34 on the side of the coarse grinding position, the Z-axis moving mechanism 22 then lowers the grinding unit 34 on the side of the coarse grinding position such that the coarse grinding stones of the grinding wheel 42a and the back surface (upper surface) 11b of the sliced SiC substrate 11 are brought into contact with each other.

As a consequence, the sliced SiC substrate 11 is subjected to coarse grinding on the side of the back surface 11b. During this time, the grinding liquid is supplied to contact interfaces (processing points) between the coarse grinding stones of the grinding wheel 42a and the back surface 11b of the sliced SiC substrate 11. The rotational speeds of the chuck table 18 and the spindle 38 during this time are each, for example, 1000 rpm or higher but 5000 rpm or lower. Further, the lowering speed of the grinding unit 34 in the state in which the coarse grinding stones of the grinding wheel 42a and the back surface 11b of the sliced SiC substrate 11 are in contact with each other is, for example, 1 μm/sec or higher but 10 μm/sec or lower.

The grinding wheel 42a at this time may be the same as that used when subjecting the sliced SiC substrate 11 to coarse grinding on the side of the front surface 11a, or may be replaced to a different one. In other words, the coarse grinding stones for use in the coarse grinding of the sliced SiC substrate 11 on the side of the back surface 11b may be the same as those for use in the coarse grinding of the sliced SiC substrate 11 on the side of the front surface 11a, or may be different ones.

The Z-axis moving mechanism 22 next raises the grinding unit 34 on the side of the coarse grinding position such that the coarse grinding stones of the grinding wheel 42a and the back surface (upper surface) 11b of the sliced SiC substrate 11 separate from each other. The rotation of both the chuck table 18 and the spindle 38 of the grinding unit 34 on the side of the coarse grinding position is then stopped. The turn table 16 is then rotated such that the chuck table 18 with the sliced SiC substrate 11 held thereon is positioned at the finish grinding position.

While rotating both the chuck table 18 and the spindle 38 of the grinding unit 34 on the side of the finish grinding position, the Z-axis moving mechanism 22 then lowers the grinding unit 34 on the side of the finish grinding position such that the finish grinding stones of the grinding wheel 42b and the back surface (upper surface) 11b of the sliced SiC substrate 11 are brought into contact with each other.

As a consequence, the sliced SiC substrate 11 is subjected to finish grinding on the side of the back surface 11b. During this time, the grinding liquid is supplied to contact interfaces (processing points) between the finish grinding stones of the grinding wheel 42b and the back surface 11b of the sliced SiC substrate 11. The rotational speeds of the chuck table 18 and the spindle 38 during this time are each, for example, 1000 rpm or higher but 5000 rpm or lower. Further, the lowering speed of the grinding unit 34 in the state in which the finish grinding stones of the grinding wheel 42b and the back surface 11b of the sliced SiC substrate 11 are in contact with each other is, for example, lower than 1 μm/sec.

The grinding wheel 42b at this time may be the same as that used when subjecting the sliced SiC substrate 11 to finish grinding on the side of the front surface 11a, or may be replaced to a different one. In other words, the finish grinding stones for use in the finish grinding of the sliced SiC substrate 11 on the side of the back surface 11b may be the same as those for use in the finish grinding of the sliced SiC substrate 11 on the side of the front surface 11a, or may be different ones.

The finish grinding of the sliced SiC substrate on the side of the back surface 11b is performed such that, after the finish grinding, the back surface 11b has an arithmetic mean height Sa of 1 nm or less. It is to be noted that an arithmetic mean height Sa is a parameter representing surface roughness as defined in ISO 25178, and is a parameter obtained by expanding an arithmetic mean height Ra, which is a parameter representing a line roughness, to a surface.

The Z-axis moving mechanism 22 next raises the grinding unit 34 on the side of the finish grinding position such that the finish grinding stones of the grinding wheel 42b and the back surface (upper surface) 11b of the sliced SiC substrate 11 separate from each other. The rotation of both the chuck table 18 and the spindle 38 of the grinding unit 34 on the side of the finish grinding position is then stopped. The grinding of the sliced SiC substrate 11 on the side of the back surface 11b (second grinding step) has now been completed.

The turn table 16 is next rotated such that the chuck table 18 with the sliced SiC substrate 11 held thereon passes the polishing position and is positioned at the loading and unloading position. The chuck table 18 positioned at the loading and unloading position is then caused to stop the suction of the sliced SiC substrate 11 on the side of the front surface (lower surface) 11a.

In a state in which the sliced SiC substrate 11 placed on the chuck table 18 is suctioned on the side of the back surface (upper surface) 11b, the transfer mechanism 78 next unloads the sliced SiC substrate 11 from the chuck table 18, and loads it into the rinsing system 80 such that the back surface 11b is directed upward. The rinsing system 80 then rinses the sliced SiC substrate 11 on the side of the back surface 11b.

With the sliced SiC substrate 11 suctioned on the side of the front surface 11a, the transfer mechanism 6 next unloads the sliced SiC substrate 11 from the rinsing system 80, and loads the sliced SiC substrate 11 onto the table 12a of the position adjustment mechanism 12 such that the front surface 11a is directed upward. The pins 12b are then brought into contact with the sliced SiC substrate 11 such that alignment of the sliced SiC substrate 11 is performed.

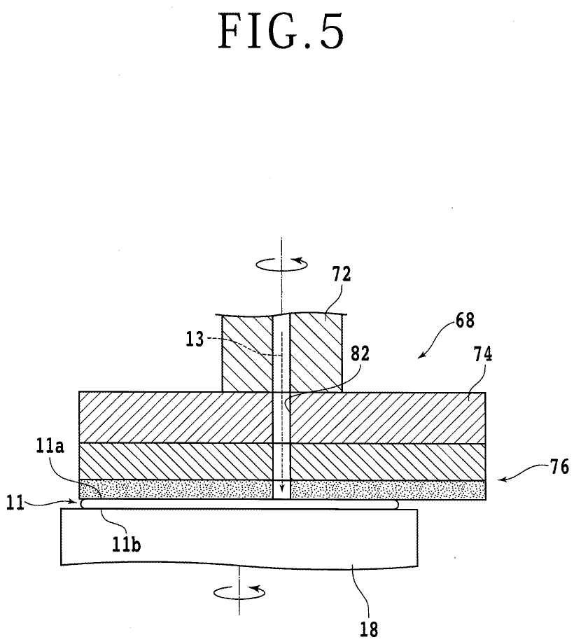

With the thus-aligned sliced SiC substrate 11 suctioned on the side of the front surface 11a, the transfer mechanism 14 next unloads the sliced SiC substrate 11 from the table 12a, and loads it onto the chuck table 18 placed at the loading and unloading position such that the front surface 11a is directed upward. The chuck table 18 with the sliced SiC substrate 11 loaded thereon then holds under suction the sliced SiC substrate 11 on the side of the back surface (lower surface) 11b. As illustrated in FIG. 5, the sliced SiC substrate 11 is next polished on the side of the front surface 11a.

Described specifically, the turn table 16 is first rotated such that the chuck table 18 with the sliced SiC substrate 11 held thereon passes the coarse grinding position and the finish grinding position and is positioned at the polishing position. While rotating both the chuck table 18 and the spindle 72 of the polishing unit 68, the Z-axis moving mechanism 56 then lowers the polishing unit 68 such that the polishing layer of the polishing pad 76 and the front surface (upper surface) 11a of the sliced SiC substrate 11 are brought into contact with each other.

As a consequence, the sliced SiC substrate 11 is polished on the side of the front surface 11a. During this time, a polishing liquid 13 is supplied from a polishing liquid supply source (not illustrated) to the front surface (upper surface) 11a of the sliced SiC substrate 11 via a through-hole 82 extending the spindle 72, the mount 74, and the polishing pad 76.

The rotational speed of the chuck table 18 during this time is, for example, 300 rpm or higher but 750 rpm or lower. Further, the rotational speed of the spindle 72 during this time is, for example, 300 rpm or higher but 1000 rpm or lower. Meanwhile, a pressure applied to the front surface 11a of the sliced SiC substrate 11 during this time is, for example, 200 g/cm² or higher but 750 g/cm² or lower.

The Z-axis moving mechanism 56 next raises the polishing unit 68 such that the polishing layer of the polishing pad 76 and the front surface (upper surface) 11a of the sliced SiC substrate 11 separate from each other. The rotation of both the chuck table 18 and the spindle 72 is then stopped. The polishing of the sliced SiC substrate 11 on the side of the front surface 11a has now been completed.

The turn table 16 is next rotated such that the chuck table 18 with the sliced SiC substrate 11 held thereon is positioned at the loading and unloading position. The chuck table 18 positioned at the loading and unloading position is then caused to stop the suction of the sliced SiC substrate 11 on the side of the back surface (lower surface) 11b.

In a state in which the sliced SiC substrate 11 placed on the chuck table 18 is suctioned on the side of the front surface (upper surface) 11a, the transfer mechanism 78 next unloads the sliced SiC substrate 11 from the chuck table 18, and loads it into the rinsing system 80 such that the front surface 11a is directed upward. The rinsing system 80 then rinses the sliced SiC substrate 11 on the side of the front surface 11a.

With the resulting SiC substrate 11 (hereinafter simply called the “SiC substrate 11”) suctioned on the side of the front surface 11a or the back surface 11b, the transfer mechanism 6 loads the SiC substrate 11 into the cassette 10b. The grinding step (S2) and the polishing step (S3) on the processing apparatus 2 have now been completed.

In the above-mentioned manufacturing method of the SiC substrate, the sliced SiC substrate 11 is ground on the side of the front surface 11a on which the Si-face is exposed, and is ground on the side of the back surface 11b on which the C-face is exposed, such that the back surface 11b has an arithmetic mean height Sa of 1 nm or less, and the sliced SiC substrate 11 is then polished only on the side of the front surface 11a and not on the side of the back surface 11b.

If the sliced SiC substrate 11 is ground on the side of the back surface 11b as described above, the warpage of the resulting SiC substrate 11 can be suppressed without the sliced SiC substrate 11 being further polished on the side of the back surface 11b. According to this manufacturing method, it is therefore possible to shorten the manufacturing lead time for a SiC substrate for use in the manufacture of power devices or the like, and to also reduce its manufacturing cost.

It is to be noted that the above-mentioned method is an embodiment of the present invention and the present invention is hence not limited to the above-mentioned method. For example, the sliced SiC substrate 11 is ground on the side of the back surface 11b after being ground on the side of the front surface 11a in the grinding step (S2) of the above-mentioned manufacturing method of the SiC substrate. In the grinding step (S2) in the present invention, the sliced SiC substrate may however be ground on the side of the front surface 11a after being ground on the side of the back surface 11b.

In this case, the sliced SiC substrate 11 held on the chuck table 18 can be polished on the side of the front surface 11a without reversing the sliced SiC substrate 11 upside down after the sliced substrate 11 is ground on the side of the front surface 11a. If this is the case, it is therefore possible to further shorten the manufacturing lead time for a SiC substrate for use in the manufacture of power devices or the like, and to also further reduce its manufacturing cost.

It is also to be noted that the configurations, procedures, and the like of the above-mentioned embodiment can be practiced with appropriate changes or modifications within the scope not departing from the object of the present invention.

### EXAMPLES

A description will hereinafter be made with regard to examples of the manufacturing method of the present invention for the SiC substrate. First, a cylindrical SiC ingot of 6 inches diameter was provided. With use of a diamond wire saw, three sliced SiC substrates were then sliced from the SiC ingot such that each sliced SiC substrate had a thickness of 500 to 600 μm and, in each sliced SiC substrate, an Si-face was exposed on a front surface and a C-face was exposed on a back surface. Coarse grinding and finish grinding were each applied to both the side of the front surface and the side of the back surface of one of the three sliced SiC substrates under the same conditions.

Described specifically, the coarse grinding was performed using a coarse grinding wheel having coarse grinding stones, which contained abrasive grits made of diamond of 14 μm average grit size, and a vitrified bond holding the abrasive grits. In that coarse grinding, the rotational speeds of the coarse grinding wheel and a chuck table with the sliced SiC substrate held thereon were each controlled at 2000 rpm. In the state in which the coarse grinding stones and the front surface or back surface of the sliced SiC substrate were in contact with each other, the lowering speed of a grinding unit was controlled at 3 μm/sec.

On the other hand, the finish grinding was performed using a finish grinding wheel having finish grinding stones, which contained abrasive grits made of diamond of 0.2 μm average grit size, and the vitrified bond holding the abrasive grits. In that finish grinding, the rotational speeds of the finish grinding wheel and a chuck table with the sliced SiC substrate held thereon were each controlled at 3000 rpm. In the state in which the finish grinding stones and the front surface or back surface of the sliced SiC substrate were in contact with each other, the lowering speed of a grinding unit was controlled at 0.15 μm/sec. As a result, a sliced SiC substrate of Example 1 (Ex. 1) was obtained.

Coarse grinding and finish grinding were next applied to the sides of both the surfaces of another one of the three sliced SiC substrates under the same conditions as those for the sliced SiC substrate in Example 1 except that the abrasive grits contained in the finish grinding stones that the finish grinding wheel had were different in average grit size. Described specifically, the finish grinding was performed using a finish grinding wheel having finish grinding stones, which contained abrasive grits made of diamond of 0.3 μm, and the vitrified bond holding the abrasive grits. As a result, a sliced SiC substrate of Example 2 (Ex. 2) was obtained.

Coarse grinding and finish grinding were next applied to the sides of both the surfaces of the remaining one of the three sliced SiC substrates under the same conditions as those for the sliced SiC substrates in Examples 1 and 2 except that the abrasive grits contained in the finish grinding stones that the finish grinding wheel had were different in average grit size. Described specifically, the finish grinding was performed using a finish grinding wheel having finish grinding stones, which contained abrasive grits made of diamond of 0.5 μm, and the vitrified bond holding the abrasive grits. As a result, a sliced SiC substrate of a comparative example (Comp. Ex.) was obtained.

The following Table 1 presents the arithmetic mean heights Sa of the back surfaces obtained after the finish grinding was applied to both the surfaces of the sliced SiC substrates in Examples 1 and 2 and the comparative example.

TABLE 1

| | Ex. 1 | Ex. 2 | Comp. Ex. |
|---|---|---|---|
| Arithmetic mean | 0.59 | 0.73 | 1.88 |
| height Sa (nm) | | | |

Polishing was next applied only to the sides of the front surfaces of the respective sliced SiC substrates of Examples 1 and 2 and the comparative example and not to the sides of their back surfaces. Described specifically, the polishing was performed using a polishing pad containing a polishing layer with abrasive grits made of SiO₂ of 0.4 to 0.6 μm grit size and dispersed in a nonwoven fabric. In the polishing, the rotational speed of the polishing pad was controlled at 745 rpm, the rotational speed of a chuck table with each SiC substrate held thereon was controlled at 750 rpm, and a pressure applied to the front surface of each sliced SiC substrate was controlled at 400 g/cm².

The following Table 2 presents the amounts of warpage of the resulting SiC substrates obtained after the polishing was applied to only the sides of the front surfaces of the respective sliced SiC substrates of Examples 1 and 2 and the comparative example and not to the sides of their back surfaces.

TABLE 2

| | Ex. 1 | Ex. 2 | Comp. Ex. |
|---|---|---|---|
| Amount of | 66.5 | 109.1 | 145.6 |
| warpage of SiC | | | |
| substrate (μm) | | | |

As presented in Tables 1 and 2, it has been found that grinding a sliced SiC substrate on the side of a front surface on which a Si-face is exposed and also grinding the sliced SiC substrate on the side of a back surface on which a C-face is exposed, such that the back surface has an arithmetic mean height Sa of 1 nm or less, enables the resulting SiC substrate to have a decreased amount of warpage even when polishing is applied to only the side of the front surface of the sliced SiC substrate and not to the side of its back surface.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A manufacturing method of a silicon carbide substrate, comprising:
a separation step of separating a sliced silicon carbide substrate from a silicon carbide ingot such that a silicon-face is exposed on a front surface and a carbon-face is exposed on a back surface;
a grinding step of, after the separation step, grinding the sliced silicon carbide substrate on both a side of the front surface and a side of the back surface of the sliced silicon carbide substrate; and
a polishing step of, after the grinding step, polishing the sliced silicon carbide substrate only on the side of the front surface and not on the side of the back surface,
wherein the grinding step includes
a first grinding step of grinding the sliced silicon carbide substrate on the side of the front surface, and
a second grinding step of grinding the sliced silicon carbide substrate on the side of the back surface, and
in the second grinding step, the sliced silicon carbide substrate is ground on the side of the back surface such that the back surface has an arithmetic mean height Sa of 1 nm or less.

2. The manufacturing method of a silicon carbide substrate according to claim 1, wherein the second grinding step is performed using grinding stones that contain abrasive grits having an average grit size of 0.3 μm or smaller.
